(19) United States
(12) Patent Application Publication
(10) Pub. No.: US 2006/0054909 A1
(43) Pub. Date: Mar. 16, 2006

(54) Light emitting diode improved in luminous efficiency

(75) Inventors: Hyoun Soo Shin, Seoul (KR); Bong II Yi, Kyungki-do (KR); Jae Chul Ro, Seoul (KR); In Joon Pyeon, Seoul (KR)

Correspondence Address: LOWE HAUPTMAN GILMAN AND BERNER, LLP, 1700 DIAGONAL ROAD, SUITE 300 /310, ALEXANDRIA, VA, 22314, US

(73) Assignee: Samsung Electro-Mechanics Co., Ltd., Kyungki-do (KR)

(21) Appl. No.: 10/993,371

(22) Filed: Nov. 22, 2004

(30) Foreign Application Priority Data
Sep. 13, 2004 (KR) 2004-73194

(51) Int. Cl. H01L 33/00

(52) U.S. Cl. 257/98

(57) ABSTRACT

The present invention relates to an LED, in which an n-doped semiconductor layer, an active layer, a p-doped semiconductor layer and a p-electrode are formed in their order on a sapphire substrate. A high reflectivity material layer containing Cu and Si is deposited on a remaining partial region of the n-doped semiconductor layer. An n-electrode is formed on the high reflectivity material layer. The high reflectivity material layer formed between the n-electrode and the partial region of the underlying n-doped semiconductor layer can reflect light toward a substrate, thereby improving the luminous efficiency of the LED.

### RELATED APPLICATION

The present application is based on, and claims priority from, Korean Application Number 2004-73194, filed Sep. 13, 2004, the disclosure of which is hereby incorporated by reference herein in its entirety.

### BACKGROUND OF THE INVENTION

1. Field of the Invention

The present invention relates to a Light Emitting Diode (LED), more particularly, which has a high reflectivity material layer formed between an n-electrode and a partial region of an underlying n-doped semiconductor layer in order to reflect light toward a substrate, thereby improving the luminous efficiency of the LED.

2. Description of the Related Art

In general, LEDs for obtaining blue or green lights are fabricated using nitride-based semiconductors such as InAlGaN.

Currently, demand for flip chip types among various LED types is increasing. In case of a flip chip type LED, light generated from an active layer is radiated to the outside directly through a sapphire substrate or after being reflected from p- and n-electrodes. As a result, the luminous efficiency of the flip chip type LED is greatly influenced by the reflectivity of p- and n-electrodes.

Hereinafter a light absorption process in an n-electrode of a conventional LED will be described with reference to FIG. 1.

As shown in FIG. 1, a flip chip type LED 100 includes a substrate 102 typically made of sapphire Al₂O₃, and an n-GaN layer 104, an active layer 106 and a p-GaN layer 108 grown in their order in the form of a mesa structure on the sapphire substrate 102. Epitaxial layers including the n-GaN layer 104, the active layer 106 and the p-GaN layer 108 are grown on the sapphire substrate 102 via Metal Organic Chemical Vapor Deposition (MOCVD).

In addition, a p-electrode 110 is formed on the p-GaN layer 108, and an n-electrode 112 is formed on a partial region of the n-GaN layer 104 on which the active layer 106 is not grown.

The p-electrode 110 is so formed to preferably cover the entire p-GaN layer 108 in order to reflect light from the active layer 108 toward the sapphire substrate 102. The p-electrode 110 can be made of a high reflectivity multilayer alloy containing Ag, Al and alloys thereof having high reflectivity or other suitable high reflectivity materials.

The n-electrode 112 is typically made of Cr/Au typically at a thickness of about 4,000 Å. The p-electrode 110 typically has a thickness of about 300 Å.

In the LED 100 having the above structure, when the active layer 106 emits light beams, they propagate along several major paths. A first light beam L1 emitted from the active layer 106 is radiated to the outside through the n-GaN layer 104 and the sapphire substrate 102. A second light beam L2 is reflected from the interface between the sapphire substrate 102 and the n-GaN layer 104 toward the p-electrode 110. Then, the second light beam L2 is reflected again from the p-electrode 110, and radiated to the outside through the p-GaN layer 108, the n-GaN layer 104 and the sapphire substrate 102. Of course, substantially the half of the light beams (not shown) from the active layer 106 will propagate directly to the p-electrode 110 through the p-GaN layer 108, and be reflected from the p-electrode 110 to the outside.

In the meantime, a third light beam L3 propagates to the n-electrode 112 after being internally reflected from the interface between the sapphire substrate 102 and the n-GaN layer 104. In the n-electrode 112 having Cr/Au double layers, however, a Cr layer attached to the n-GaN layer 104 has a reflectivity relatively lower than that of Ag or Al and thus absorbs the light beam L3 rather than reflecting the same. This as a result causes light loss and therefore lowers the luminous efficiency of the LED 100.

Accordingly, for example replacement of Cr/Au of the n-electrode with a high reflectivity material may improve the reflectivity of the n-electrode so as to prevent light absorption in the n-electrode, thereby improving the luminous efficiency of the LED.

### SUMMARY OF THE INVENTION

The present invention has been made to solve the foregoing problems of the prior art and it is therefore an object of the present invention to provide a high reflectivity material layer between an n-electrode and a partial region of an underlying n-doped semiconductor layer in order to reflect light toward a substrate thereby improving the luminous efficiency of an LED.

It is another object of the invention to add Cu and Si into the high reflectivity material layer deposited between the n-electrode and the partial region of the underlying n-doped semiconductor layer in order to improve the stability of the high reflectivity material layer thereby improving the stability and reliability of the LED.

According to an aspect of the invention for realizing the object, there is provided an LED comprising: a sapphire substrate; an n-doped semiconductor layer grown on the sapphire substrate; an active layer grown on a major region of the n-doped semiconductor layer; a p-doped semiconductor layer grown on the active layer; a p-electrode formed on the p-doped semiconductor layer; a high reflectivity material layer deposited on a remaining region of the n-doped semiconductor layer, the high reflectivity material layer containing Cu and Si; and an n-electrode formed on the high reflectivity material layer.

Preferably, the high reflectivity material layer is made of at least one selected from the group consisting of Ag, Al, Pd, Rh and alloys thereof.

The high reflectivity material layer contains preferably Cu of about 0.2 to 0.8 wt % and Si of about 0.5 to 2 wt %, and more preferably Cu of about 0.5 to 0.7 wt % and Si of about 0.9 to 1 wt %.

Preferably, the high reflectivity material layer is deposited via sputtering or electron beam deposition.

The high reflectivity material layer has a thickness preferably of about at least 300 Å, and more preferably of about 1,000 to 2,000 Å.

Also, the LED of the invention may further comprise an intermediate layer interposed between the high reflectivity material layer and the n-electrode, the intermediate layer being made of a material having a high bonding force to both the high reflectivity material layer and the n-electrode.

Preferably, the intermediate layer is made of Ni.

The intermediate layer has a thickness preferably of about at least 500 Å, and more preferably of about 1,000 to 4,000 Å.

In addition, the LED of the invention may further comprise a conductive oxide layer interposed between the remaining region of the n-doped semiconductor layer and the high reflectivity material layer.

Preferably, the conductive material layer is made of at least one selected from the group consisting of Indium Tin Oxide (ITO), Copper Indium Oxide (CIO) and Magnesium Indium Oxide (MIO).

Preferably, the remaining region of the n-doped semiconductor layer has a vertically patterned top surface.

Furthermore, the sapphire substrate may be replaced with one selected from the group consisting of a silicon carbide (SiC) substrate, an oxide substrate and a carbide substrate.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a cross-sectional view of an LED of the prior art, which illustrates light loss occurring in an n-electrode;

FIG. 2 is a cross-sectional view of an LED according to a first embodiment of the invention, which illustrates light reflected from an n-electrode;

FIG. 3 is a cross-sectional view of an LED according to a second embodiment of the invention, which illustrates light reflected from an n-electrode;

FIG. 4 is a cross-sectional view of an LED according to a third embodiment of the invention, which illustrates light reflected from an n-electrode;

FIG. 5 is a plan view of an exemplary LED structure to which the invention is applicable;

FIG. 6 is a plan view of another exemplary LED structure to which the invention is applicable; and

FIG. 7 is a graph for comparing luminous efficiencies of LEDs of the invention and the prior art.

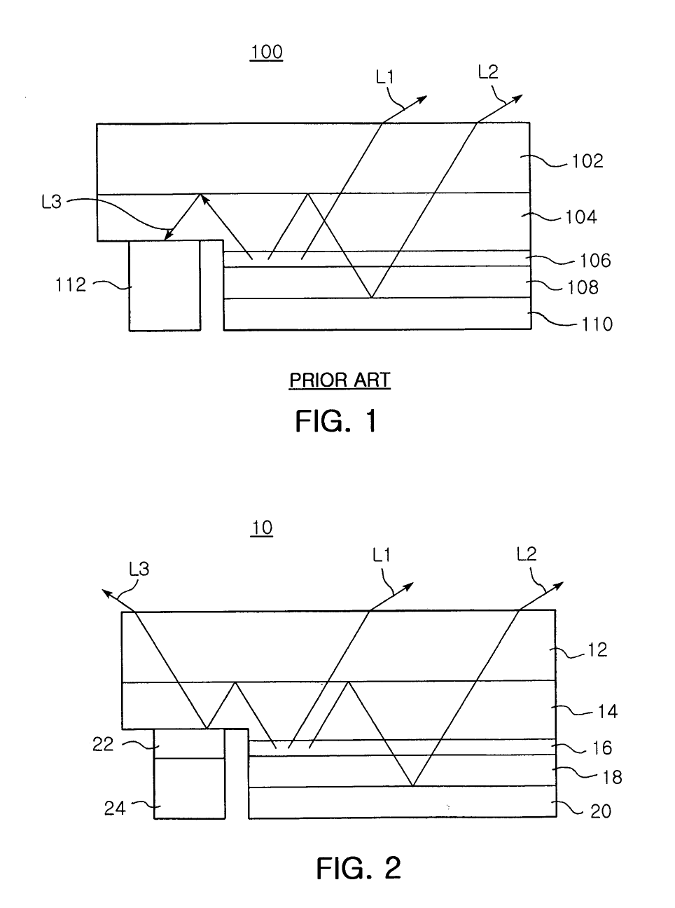

### DETAILED DESCRIPTION OF THE PREFERRED EMBODIMENT

Preferred embodiments of the present invention will now be described in detail with reference to the accompanying drawings.

FIG. 2 is a cross-sectional view of an LED according to a first embodiment of the invention, which illustrates light reflected from an n-electrode.

As shown in FIG. 2, an LED 10 of the invention has an improved luminous efficiency, and includes a substrate 12 of for example sapphire (Al₂O₃), an n-doped semiconductor layer 14 of for example n-GaN grown on the sapphire substrate 12, an active layer 16 grown on a first region occupying a major portion of the n-doped semiconductor layer 14 and a p-doped semiconductor layer 18 of for example-p-GaN grown on the active layer 16. The n-doped semiconductor layer 14, the active layer 16 and the p-doped semiconductor layer 18 are epitaxially grown via Metal Organic Chemical Vapor Deposition (MOCVD), and then etched into a mesa structure to expose a second region of the n-doped semiconductor layer 14 except for the first region.

The LED 10 improved in luminous efficiency includes a p-electrode 20 formed on the p-doped semiconductor layer 18. The p-electrode 20 is so formed to preferably cover the entire p-doped semiconductor layer 18 to reflect a light beam L2 emitted from the active layer 18 toward the substrate 12. The p-electrode 20 can be made of a high reflectivity multilayer alloy containing any one of Ag, Al and alloys thereof having high reflectivity or any one of other suitable high reflectivity materials and alloys thereof.

A high reflectivity material layer 22 is formed in the remaining second region of the n-doped semiconductor layer 14, and an n-electrode 24 is formed on the high reflectivity material layer 22.

The high reflectivity material layer 22 is made basically of a high reflectivity material containing Cu and Si, and deposited on the second region of the n-doped semiconductor layer 14 via sputtering or electron beam deposition.

In the sputtering, sputtering gas is flown into a vacuum chamber and collides against a target forming plasma from target material so that the plasma is coated in the form of a thin film on a substrate. Generally, the sputtering gas utilizes inactive gas such as Ar.

Describing the sputtering process in brief, when a voltage is applied to the target as a cathode and a substrate as an anode, sputtering gas is excited into Ar⁺ ions through collision with electrons emitted from the anode. Then, Ar⁺ ions are attracted toward and collide against the target as the anode. Since the excited Ar⁺ ions each have a predetermined energy hν, the energy is transferred into the target during collision. When the energy exceeds the bonding force of a target element and the work function of electrons, plasma is emitted from the target. The plasma rises up to the free path of electrons, and when the substrate is spaced from the target within the free path, forms a thin film on the substrate.

A type of the sputtering using a DC voltage is referred to as DC sputtering, and generally used for the deposition of conductors. In case of nonconductors such as insulators, thin films are formed via AC sputtering using an AC voltage. The AC sputtering is also referred to as Radio Frequency (RE) sputtering since it uses an AC voltage typically having a frequency of 13.56 MHz.

The electron beam deposition uses electron beams to heat a holder in a high vacuum atmosphere (i.e., 5×10⁻⁵ to 1×10⁻⁷ torr) In this fashion, metal on the holder is melted and evaporated so that metal vapors are condensed on the surface of a wafer that is relatively cold. The electron beam deposition is mainly used for the fabrication of thin films on semiconductor wafers.

In the meantime, examples of suitable high reflectivity material may include Ag, Al, Pd, Rh and alloys thereof. Each material, together with Cu and Si, maybe deposited individually or in combination with other material on the second region of the n-semiconductor layer 14 via the sputtering or electron beam deposition.

When deposited on the n-doped semiconductor layer 14, the high reflectivity materials can realize an excellent reflecting layer by virtue of their high reflectivity. When deposited individually, the high reflectivity materials may suffer from hill-lock or electro-migration that may damage the stability of a high reflectivity material layer. In order to prevent this, a suitable quantity of Cu and Si are added into the high reflectivity materials. Generally, Cu functions to prevent the hill-lock of any deposited high reflectivity material, and Si functions to prevent electro-migration.

In this case, the Cu content in the high reflectivity material layer 22 is about 0.2 to 0.8 wt %, and the Si content in the high reflectivity material layer 22 is about 0.5 to 2 wt %. Preferably, the high reflectivity material layer 22 contains about 0.6 to 0.7 wt % Cu and about 0.9 to 1 wt % Si.

In the LED 10 having the above structure, when the active layer 16 emits light beams, they propagate along several major paths. A first light beam L1 emitted from the active layer 16 is radiated to the outside through the n-doped semiconductor layer 14 and the sapphire substrate 12. A second light beam L2 is reflected from the interface between the sapphire substrate 12 and the n-doped semiconductor layer 14 toward the p-electrode 20. Then, the second light beam L2 is reflected again from the p-electrode 20, and radiated to the outside through the p-doped semiconductor layer 18, the n-doped semiconductor layer 14 and the sapphire substrate 12. Of course, substantially the half of the light beams (not shown) from the active layer 16 will propagate directly to the p-electrode 20 through the p-doped semiconductor layer 18, and be reflected therefrom to the outside.

In the meantime, a third light beam L3 propagates to the high reflectivity material layer 22 after being internally reflected from the interface between the sapphire substrate 12 and the n-doped semiconductor layer 14. The high reflectivity material layer 22 reflects the light beam L3 since it has a high reflectivity as described above. Accordingly, unlike the conventional n-electrode of Cr/Au, the LED 10 of the invention does not suffer from light loss in the n-electrode 24 by absorption, thereby greatly improving luminous efficiency.

In this case, the high reflectivity material layer 22 has a thickness of about at least 300 Å in order to realize desired functions. Preferably, the high reflectivity material layer 22 has a thickness of about 1,000 to 2,000 Å.

Unlike the conventional n-electrode absorbing most of light, the high reflectivity material layer 22 deposited on the n-electrode 24 can reflect light toward the substrate 12, thereby improving the luminous efficiency of the LED 10 for about 16%. The improvement in luminous efficiency will be described in detail later in the specification.

In the meantime, the second region of the n-doped semiconductor layer 14 as a underlying area of the high reflectivity material layer 22 can be vertically patterned before the deposition of the high reflectivity material layer 22 so as to further improve the reflectivity in this region.

Furthermore, the sapphire substrate 12 of the LED 10 of the invention can be replaced with one selected from the group consisting of a silicon carbide (SiC) substrate, an oxide substrate and a carbide substrate.

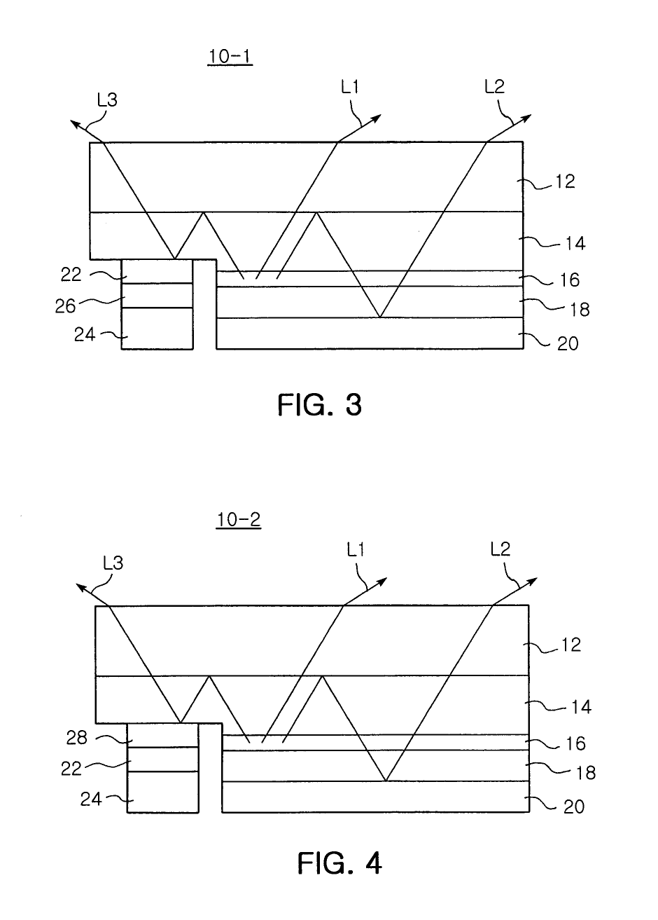

FIG. 3 is a cross-sectional view of an LED according to a second embodiment of the invention, which illustrates light reflected from an n-electrode.

Referring to FIG. 3, an LED 10-1 according to the second embodiment of the invention has a structure substantially similar to that of the LED 10 of the first embodiment shown in FIG. 2. That is, the LED 10-1 includes an n-doped semiconductor layer 14 (e.g., of n-GaN), an active layer 16, a p-doped semiconductor layer 18 (e.g., p-GaN) and a p-electrode 20, which are formed in their order on the substrate 12 into a mesa structure. Structures and forming techniques of these components are substantially the same as those of the first embodiment as described above.

In addition, a high reflectivity material layer 22, an intermediate layer 26 and an n-electrode 24 are formed on a partial first region of the n-doped semiconductor layer 14. The high reflectivity material layer 22 and the n-electrode 24 will not be described further since they are substantially the same as those of the first embodiment as described above.

The intermediate layer 26 is provided to ensure reliable bonding between the high reflectivity material layer 22 and the n-electrode 24, and preferably made of Ni. That is, since the high reflectivity material layer 22 made of at least one selected from Ag, Al, Pd, Rd and alloys thereof may not bond well with the n-electrode 24 typically made of Au, the intermediate layer 26 made of Ni, which finely bonds with both materials of the high reflectivity material layer 22 and the n-electrode 24, can be interposed between the high reflectivity material layer 22 and the n-electrode 24 to ensure excellent bonding between the high reflectivity material layer 22 and the n-electrode 24.

In this case, the intermediate layer 26 preferably has a thickness of about at least 500 Å, and more preferably has a thickness of about 1,000 to 4,000 Å.

The LED 10-1 of the second embodiment can improve stability and reliability more while realizing excellent luminous efficiency the same as that of the LED 10 of the first embodiment.

In the LED 10-1 of the second embodiment, the second region of the n-doped semiconductor layer 14 as an underlying area of the high reflectivity material layer 22 can be vertically patterned before the deposition of the high reflectivity material layer 22 to further improve reflectivity as in the LED 10 of the first embodiment.

In addition, the sapphire substrate 12 of the LED 10-1 of the invention can be replaced with one selected from the group consisting of a SiC substrate, an oxide substrate and a carbide substrate.

FIG. 4 is a cross-sectional view of an LED according to a third embodiment of the invention, which illustrates light reflected from an n-electrode.

Referring to FIG. 4, the LED 10-2 according to the third embodiment of the invention has a structure substantially similar to that of the LED 10 of the first embodiment shown in FIG. 2. That is, the LED 10-2 includes an n-doped semiconductor layer 14 (e.g., of n-GaN), an active layer 16, a p-doped semiconductor layer 18 (e.g., p-GaN) and a p-electrode 20, which are formed in their order on a sapphire substrate 12 into a mesa structure. Structures and forming techniques of these components are substantially the same as those of the first embodiment as described above.

In addition, a conductive oxide layer 28, a high reflectivity material layer 22 and an n-electrode 24 are formed on a partial second region of the n-doped semiconductor layer 14. The high reflectivity material layer 22 and the n-electrode 24 will not be described further since they are substantially the same as those of the first embodiment as described above.

The conductive oxide layer 28 is made of at least one selected from the group consisting of Indium Tin Oxide (ITO), Copper Indium Oxide (CIO) and Magnesium Indium Oxide (MIO). The conductive oxide layer 28 can promote adsorption between the n-doped semiconductor layer 14 and the high reflectivity material layer 22 while preventing hill-lock or electro-migration in the high reflectivity material layer 22, thereby improving the stability and reliability of lighting capability of the LED 10-2.

The LED 10-2 of this embodiment may further include the foregoing intermediate layer 26 of the second embodiment. That is, the intermediate layer 26 of for example Ni can be further interposed between the high reflectivity material layer 22 and the n-electrode 24 so as to further improve the stability and reliability of the LED 10-2.

In the LED 10-2, the second region of the n-doped semiconductor layer 14 as an underlying area of the conductive oxide layer 28 can be also vertically patterned before the deposition of the conductive oxide layer 28 to further improve reflectivity as in the LED 10 of the first embodiment.

In addition, the sapphire substrate 12 of the LED 10-2 of the invention can be replaced with one selected from the group consisting of a SiC substrate, an oxide substrate and a carbide substrate.

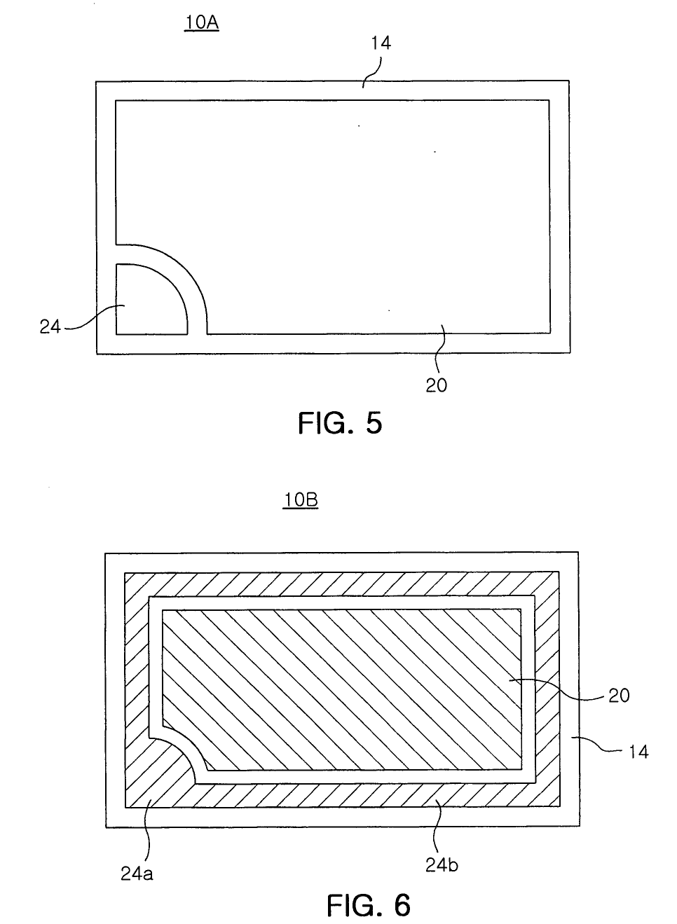

FIG. 5 is a plan view of an exemplary LED structure to which the invention is applicable, and FIG. 6 is a plan view of another exemplary LED structure to which the invention is applicable.

An LED 10A shown in FIG. 5 has a typical flip chip type LED structure, which has an n-electrode 24 formed at a corner of the LED 10A and a p-electrode 20 formed in the rest of the LED 10A. Therefore, it will be understood that improvement in the reflectivity of the corner region occupied by the n-electrode 24 can improve the reflectivity of the entire LED 10A.

In an LED 10B shown in FIG. 6, an n-electrode includes a contact 24a formed at a corner of the LED 10B and a finger 24b formed around a p-electrode 24 along the outer circumference of the LED 10B. This structure is designed to improve the current crowding between p- and n-electrodes, and the application of the LED of the invention to this structure can further improve luminous efficiency.

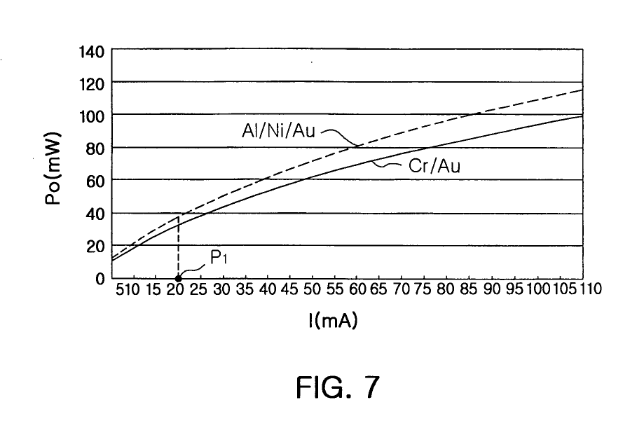

FIG. 7 is a graph for comparing luminous efficiencies of LEDs of the invention and the prior art.

An LED structure according to the second embodiment of the invention as shown in FIG. 3 was selected with a 320×300 chip size and a two-dimensional configuration as shown in FIG. 5. The LED had a high reflectivity material layer which was mainly made of Al containing 1 wt % Cu and 0.5 wt % Si at a thickness of 2,000 Å. An intermediate layer was made of Ni at a thickness of 2,000 Å, and an n-electrode was made of Au at a thickness of 4,000 Å.

On the other hand, a conventional 320×300 chip size LED was used, in which a Cr layer of an n-electrode has a thickness of 300 Å and a Au layer thereof had a thickness of 4,000 Å.

Results as shown in FIG. 7 were obtained from a light intensity test to the LED (Al/Ni/Au) of the invention and the convention LED (Cr/Au). It was proved that the LED (Al/Ni/Au) of the invention had more excellent light intensity than the conventional LED (Cr/Au) and the light intensity difference was increased in proportion to current intensity.

For example, at a point P1 where a current of 20 mA was applied, the LED (Al/Ni/Au) of the invention had a light intensity of 37.12 mW, and the conventional LED (Cr/Au) had a light intensity of 32.02 mW. At this point P1, the light intensity of the inventive LED (Al/Ni/Au) was about 16% superior to that of the conventional LED (Cr/Au).

According to the invention as described above, the high reflectivity material layer formed between the n-electrode and the partial region of the n-doped semiconductor layer can reflect light toward the substrate, thereby significantly improving the luminous efficiency of the LED.

Also, the addition of Cu and Si into the high reflectivity material layer can improve the stability of the high reflectivity material layer, thereby improving the stability and reliability of the LED.

In addition, the intermediate layer of for example Ni formed between the high reflectivity material layer and the n-electrode can improve the bonding between the high reflectivity material layer and the n-electrode thereby improving the stability and reliability of the LED.

While the present invention has been shown and described in connection with the preferred embodiments, it will be apparent to those skilled in the art that modifications and variations can be made without departing from the spirit and scope of the invention as defined by the appended claims.

What is claimed is:

1. A Light Emitting Diode (LED) comprising:
a sapphire substrate;
an n-doped semiconductor layer grown on the sapphire substrate;
an active layer grown on a major region of the n-doped semiconductor layer;
a p-doped semiconductor layer grown on the active layer;
a p-electrode formed on the p-doped semiconductor layer;
a high reflectivity material layer deposited on a remaining region of the n-doped semiconductor layer, the high reflectivity material layer containing Cu and Si; and
an n-electrode formed on the high reflectivity material layer.

2. The LED according to claim 1, wherein the high reflectivity material layer is made of at least one selected from the group consisting of Ag, Al, Pd, Rh and alloys thereof.

3. The LED according to claim 1, wherein the high reflectivity material layer contains Cu of about 0.2 to 0.8 wt % and Si of about 0.5 to 2 wt %.

4. The LED according to claim 1, wherein the high reflectivity material layer contains Cu of about 0.5 to 0.7 wt % and Si of about 0.9 to 1 wt %.

5. The LED according to claim 1, wherein the high reflectivity material layer is deposited via sputtering or electron beam deposition.

6. The LED according to claim 1, wherein the high reflectivity material layer has a thickness of about at least 300 Å.

7. The LED according to claim 1, wherein the high reflectivity material layer has a thickness of about 1,000 to 2,000 Å.

8. The LED according to claim 1, further comprising an intermediate layer interposed between the high reflectivity material layer and the n-electrode, the intermediate layer being made of a material having a high bonding force to both the high reflectivity material layer and the n-electrode.

9. The LED according to claim 8, wherein the intermediate layer is made of Ni.

10. The LED according to claim 8, wherein the intermediate layer has a thickness of about at least 500 Å.

11. The LED according to claim 8, wherein the intermediate layer has a thickness of about 1,000 to 4,000 Å.

12. The LED according to claim 8, further comprising a conductive oxide layer interposed between the remaining region of the n-doped semiconductor layer and the high reflectivity material layer.

13. The LED according to claim 12, wherein the conductive material layer is made of at least one selected from the group consisting of Indium Tin Oxide (ITO), Copper Indium Oxide (CIO) and Magnesium Indium Oxide (MIO).

14. The LED according to claim 1, further comprising a conductive oxide layer interposed between the remaining region of the n-doped semiconductor layer and the high reflectivity material layer.

15. The LED according to claim 14, wherein the conductive material layer is made of at least one selected from the group consisting of Indium Tin Oxide (ITO), Copper Indium Oxide (CIO) and Magnesium Indium Oxide (MIO).

16. The LED according to claim 1, wherein the remaining region of the n-doped semiconductor layer has a vertically patterned top surface.

17. The LED according to claim 1, wherein the sapphire substrate is replaced with one selected from the group consisting of a silicon carbide (SiC) substrate, an oxide substrate and a carbide substrate.
